(19) United States
(12) Patent Application Publication
(10) Pub. No.: US 2022/0030745 A1
(43) Pub. Date: Jan. 27, 2022

(54) SYSTEM AND METHOD FOR SERVICE LIFE MANAGEMENT BASED ON LOCAL COOLING MANAGEMENT

(71) Applicant: Dell Products L.P., Hopkinton, MA (US)

(72) Inventors: Steven Embleton, Austin, TX (US); Jon Taylor Fitch, Austin, TX (US)

(21) Appl. No.: 16/938,738

(22) Filed: Jul. 24, 2020

(51) Int. Cl. H05K 7/20

(52) U.S. Cl. CPC H05K 7/20209; H05K 7/20145

(57) ABSTRACT

A chassis includes a first computing component; a second computing component; and an air mover that generates an airflow in the chassis used to thermally manage the first computing component and the second computing component. The chassis also includes an airflow control component that modifies a first portion of the airflow proximate to the first computing component based on a corrosion rate of the first computing component without modifying a second portion of the airflow proximate to the second computing component.

### BACKGROUND

As the value and use of information continues to increase, individuals and businesses seek additional ways to process and store information. One option available to users is information handling systems. An information handling system (IHS) generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Use cases for information handling systems are causing progressively larger number of information handling systems to be disposed near each other. For example, rack mount systems utilize a rack structure to stack many information handling systems in a vertical arrangement. Due to the changing uses of information handling systems, chassis of information handling systems may modular. That is, a chassis may be composed of multiple enclosures that may be attached to each other to form the chassis of the information handling systems. When the multiple enclosures are attached, components of the information handling system disposed in each of the enclosures may become operably connected to each other.

### SUMMARY

In one aspect, a chassis in accordance with one or more embodiments of the invention includes a first computing component; a second computing component; an air mover that generates an airflow in the chassis used to thermally manage the first computing component and the second computing component; and an airflow control component that modifies a first portion of the airflow proximate to the first computing component based on a corrosion rate of the first computing component without modifying a second portion of the airflow proximate to the second computing component.

In one aspect, a method for environmentally managing a chassis of an information handling system in accordance with one or more embodiments of the invention includes thermally managing a first computing component of the information handling system using a first portion of an airflow; thermally managing a second computing component of the information handling system using a second portion of the airflow; while thermally managing the first computing component and the second computing component: modifying the first portion of the airflow based on a corrosion rate of the first computing component without modifying the second portion of the airflow.

In one aspect, a non-transitory computer readable medium in accordance with one or more embodiments of the invention includes computer readable program code, which when executed by a computer processor enables the computer processor to perform a method for environmentally managing a chassis of an information handling system. The method includes thermally managing a first computing component of the information handling system using a first portion of an airflow; thermally managing a second computing component of the information handling system using a second portion of the airflow; while thermally managing the first computing component and the second computing component: modifying the first portion of the airflow based on a corrosion rate of the first computing component without modifying the second portion of the airflow.

### BRIEF DESCRIPTION OF DRAWINGS

Certain embodiments of the invention will be described with reference to the accompanying drawings. However, the accompanying drawings illustrate only certain aspects or implementations of the invention by way of example and are not meant to limit the scope of the claims.

FIG. 1.1 shows a diagram of an information handling system in accordance with one or more embodiments of the invention.

FIG. 1.2 shows a diagram of a building that includes information handling systems in accordance with one or more embodiments of the invention.

FIG. 1.3 shows a diagram of a chassis of an information handling system in accordance with one or more embodiments of the invention.

FIG. 1.4 shows a diagram of computing components in accordance with one or more embodiments of the invention.

FIG. 1.5 shows a diagram of an active airflow control component in accordance with one or more embodiments of the invention.

FIG. 1.6 shows a diagram of a passive airflow control component in accordance with one or more embodiments of the invention.

FIG. 2 shows a diagram of an environmental manager of an information handling system in accordance with one or more embodiments of the invention.

FIG. 3 shows a diagram of an example lifecycle repository in accordance with one or more embodiments of the invention.

FIG. 4.1 shows a flowchart of a method of managing an internal environment of a chassis of an information handling system in accordance with one or more embodiments of the invention.

FIG. 4.2 shows a flowchart of a method of performing an environmental analysis in accordance with one or more embodiments of the invention.

FIGS. 5.1-5.3 show a top view diagram of an example ejector chassis of an information handling system over time.

FIG. 6 shows a diagram of a computing device in accordance with one or more embodiments of the invention.

### DETAILED DESCRIPTION

Specific embodiments will now be described with reference to the accompanying figures. In the following description, numerous details are set forth as examples of the invention. It will be understood by those skilled in the art that one or more embodiments of the present invention may be practiced without these specific details and that numerous variations or modifications may be possible without departing from the scope of the invention. Certain details known to those of ordinary skill in the art are omitted to avoid obscuring the description.

In the following description of the figures, any component described with regard to a figure, in various embodiments of the invention, may be equivalent to one or more like-named components described with regard to any other figure. For brevity, descriptions of these components will not be repeated with regard to each figure. Thus, each and every embodiment of the components of each figure is incorporated by reference and assumed to be optionally present within every other figure having one or more like-named components. Additionally, in accordance with various embodiments of the invention, any description of the components of a figure is to be interpreted as an optional embodiment, which may be implemented in addition to, in conjunction with, or in place of the embodiments described with regard to a corresponding like-named component in any other figure.

In general, embodiments of the invention relate to systems, devices, and methods for managing components of an information handling system. An information handling system may be a system that provides computer implemented services. These services may include, for example, database services, electronic communication services, data storage services, etc.

To provide these services, the information handling system may include one or more computing devices. The computing devices may include any number of computing components that facilitate providing of the services of the information handling system. The computing components may include, for example, processors, memory modules, circuit cards that interconnect these components, etc.

During operation, these components may be exposed to gases that may cause the components to corrode. Corrosion may cause the components to fail prior to the computing device meeting its service life goals.

Embodiments of the invention may provide methods and systems that reduce the risk of corrosion related failures in information handling systems. To reduce the risk of corrosion related failures, the system may manage the components based, in part, on their risk of corrosion. To monitor their risk of corrosion, the rates of corrosion within the environments in which the components reside may be measured. By measuring the rates of corrosion within the environments, the impact of water vapor, chemically reactive species, temperature, and/or other factors that impact corrosion may be taken into account. If the rate of corrosion is sufficient to risk premature failure of the components due to corrosion, the system may modify the environment proximate to the components to decrease the rate of corrosion.

To modify the environment, the system may increase the temperature of the ambient environment. For example, the system may utilize a passive flapper that prevents, on a granular level, airflow from reaching the computing components. As a second example, the system may utilize a heating component that heats the ambient environment of a set of one or more computing components whenever a risk of corrosion in the set of computing components is high (e.g., whenever the relative humidity in the ambient environment near the computing components is high). The rate of corrosion may be reduced to a level that the information handling system is likely to meet its service life goal prior to its components failing due to corrosion.

By doing so, a system in accordance with embodiments of the invention may be less likely to prematurely fail, be more likely to meet its service life goal, be able to accept a wider range of intake gas conditions, and/or may be less costly to operate by reducing the level of conditioning of gases taken into the chassis of the information handling systems.

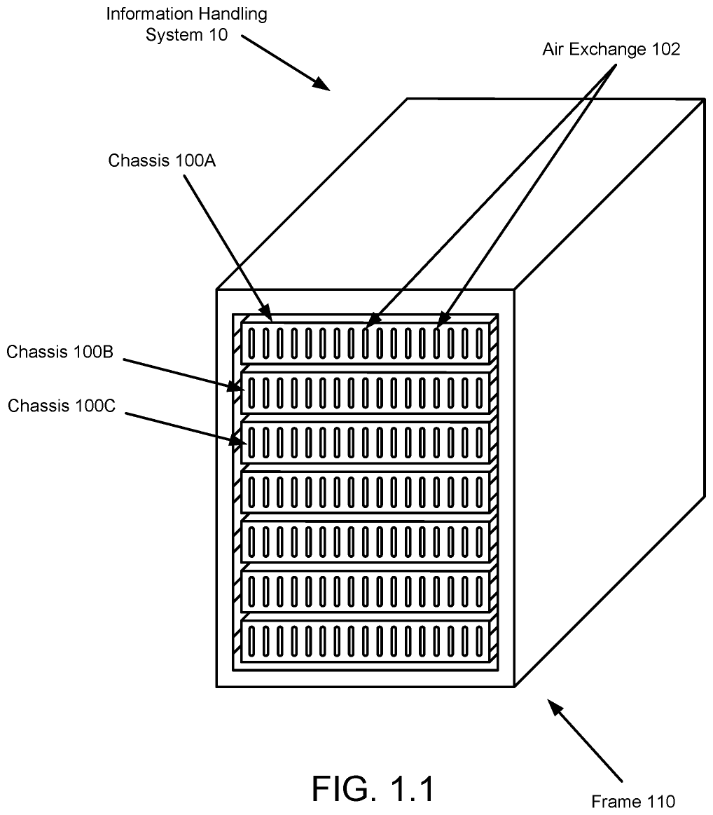

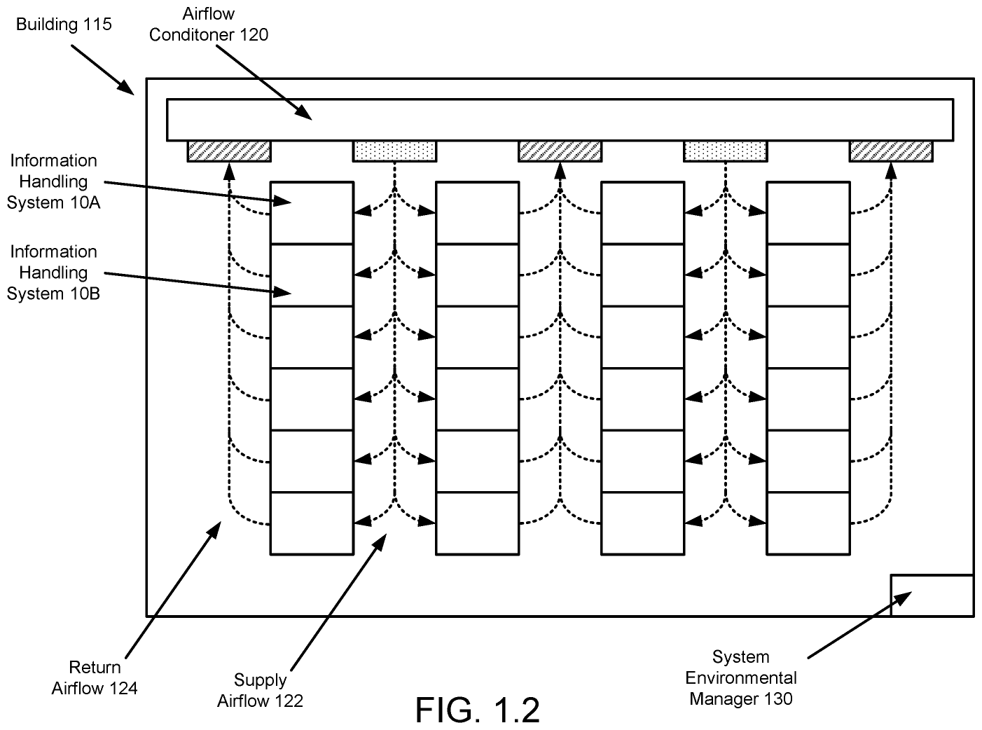

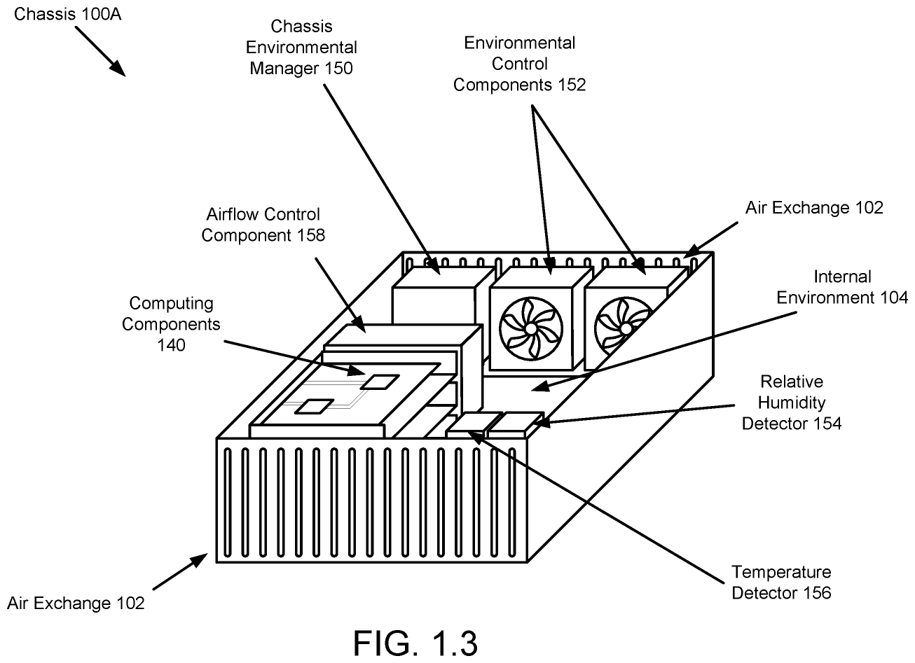

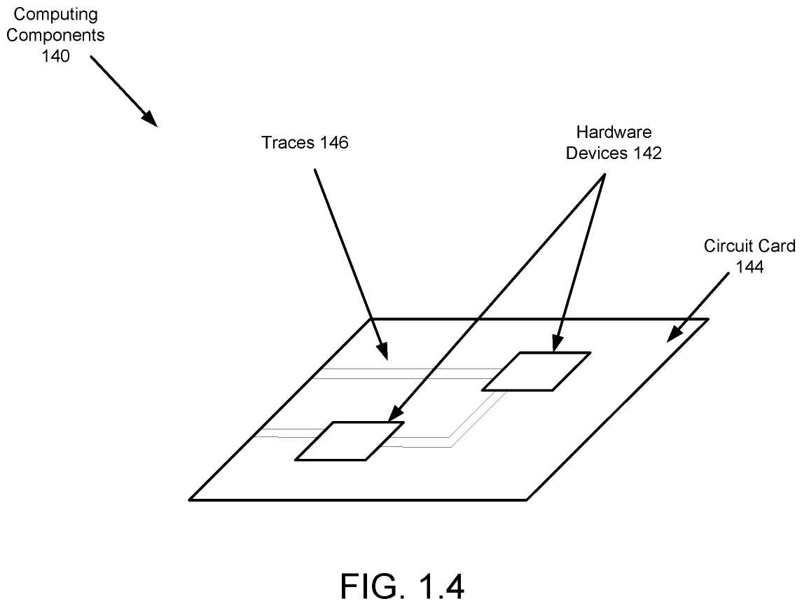

FIG. 1.1 shows an information handling system (10) in accordance with one or more embodiments of the invention. The system may include a frame (110) and any number of chassis (e.g., 100A, 100B, 100C).

The frame (110) may be a mechanical structure that enables chassis to be positioned with respect to one another. For example, the frame (110) may be a rack mount enclosure that enables chassis to be disposed within it. The frame (110) may be implemented as other types of structures adapted to house, position, orient, and/or otherwise physically, mechanically, electrically, and/or thermally manage chassis. By managing the chassis, the frame (110) may enable multiple chassis to be densely packed in space without negatively impacting the operation of the information handling system (10).

A chassis (e.g., 100A) may be a mechanical structure for housing components of an information handling system. For example, a chassis may be implemented as a rack mountable enclosure for housing components of an information handling system. The chassis may be adapted to be disposed within the frame (110) and/or utilize services provided by the frame (110) and/or other devices.

Any number of components may be disposed in each of the respective chassis (e.g., 100A, 100B, 100C). These components may be portions of computing devices that provide computer implemented services, discussed in greater detail below.

When the components provide computer implemented services, the components may generate heat. For example, the components may utilize electrical energy to perform computations and generate heat as a byproduct of performing the computations. If left unchecked, buildup of heat within a chassis may cause temperatures of the components disposed within the chassis to exceed preferred ranges.

The preferred ranges may include a nominal range in which the components respectively operate (i) without detriment and/or (ii) are likely to be able to continue to operate through a predetermined service life of a component. Consequently, it may be desirable to maintain the temperatures of the respective components within the preferred range (e.g., a nominal range).

When a component operates outside of the preferred range, the service life of the component may be reduced, the component may not be able to perform optimally (e.g., reduced ability to provide computations, higher likelihood of error introduced into computations, etc.), and/or the component may be more likely to unexpectedly fail. The component may be subject to other undesirable behavior when operating outside of the preferred range without departing from the invention.

To operate components within the preferred range of temperature, the chassis may include air exchanges (e.g., 102). An air exchange (102) may be one or more openings in an exterior of a chassis that enables the chassis to exchange gases with an ambient environment. For example, a chassis may utilize air exchanges to (i) vent hot gases and (ii) intake cool gases. By doing so, the temperature of the gases within the chassis may be reduced. Consequently, the temperatures of components within the chassis may be reduced by utilizing the cooler gases taken into the chassis via an air exchange.

However, utilizing gases to cool components within a chassis may be problematic. The gases may not be benign. For example, the gases may be (i) chemically reactive, (ii) include humidity, and/or (iii) otherwise interact with components disposed within the chassis in an undesirable manner. The reaction between the gases used to cool the components and the components themselves (or other components proximate to the to-be-cooled components) may negatively impact the components disposed within the chassis.

For example, if the gases include a chemically reactive component (e.g., chlorine species), the gases may react (i.e., chemically react) with portions of the components disposed within the chassis. These reactions may damage portions of the components resulting in a decreased service life of the components.

In another example, if the gases include humidity, the humidity may condense resulting in water being disposed on the surface of the components. When water is disposed on the surface of components (even at very small levels), the water may chemically react with the components forming corrosion. The aforementioned reactions with the condensed water may damage the components or otherwise cause them to operate in an undesirable manner.

The potential reactions, discussed above, may cause numerous negative impacts. First, the reactions may impact the electrical conductivity of various components. For example, when metals react with chemically reactive species, condensed water vapor, etc., the metals may form chemical compounds that are substantially less conductive than the pure metals. The reduced conductivities of the components may negatively impact the electrical functionality of the components (e.g., circuits) disposed within the chassis.

Second, the reactions may impact the physical size of various components. For example, when metals chemically react, the products formed by the reactions may occupy significantly larger volumes than the unreacted metals (e.g., metal oxides vs elemental metals). The change in volumes of the reacted metals may negatively impact the electrical functionality of the components by, for example, forming open circuits by physically disconnecting various portions of the components from each other and/or other devices.

The potential reactions may cause other negative impacts beyond those discussed herein. The negative impacts may cause a device to fail prior to it meeting its service life. A service life may be a desired duration of operation of a component, device, or system.

To address the above and/or other potential issues, embodiments of the invention may provide methods, devices, and systems that manage environments within chassis. The environments may be managed to reduce the occurrence of reactions, between gases (that may include water vapor and/or reactive species) and components, that result in a reduction of the service life of (i) the component, (ii) a computing device of which the component is a member, and/or (iii) an IHS that incorporates the component due to premature failure of the aforementioned entities.

An environment within a chassis may be managed by reducing the likelihood of chemical reactions occurring due to the presence of condensed water vapor. To reduce the likelihood of chemical reactions occurring, the temperature and/or humidity level (e.g., relative humidity) may be manipulated to (i) reduce the likelihood of condensation from occurring, (ii) reduce the rate of chemical reactions occurring, and/or (iii) ensure that temperatures of components are within the predetermined ranges in which the operation of the components is nominal (e.g., to limit premature failure of components due to thermal conditions).

To determine how to manage the environment within the chassis, a system may monitor the actual rates of corrosion occurring within the chassis. The measured rates may be used alone or in conjunction with estimated rates of corrosion not measured directly to ascertain the corrosion rates occurring throughout the chassis. Based on the ascertained corrosion rates, the system may modify (i) the temperature within the chassis, (ii) humidity level within the chassis, (iii) gas flow rates within the chassis, (iv) temperature of gases being taken into the chassis for cooling purposes, and/or (v) source of gases being taken into the chassis for cooling purposes. The aforementioned modifications may be made to (a) limit the rate of corrosion, (b) reduce the cost of conditioning gases used for cooling purposes, and/or (c) meeting service life goals.

To further clarify the processes of managing the environments within the chassis, a diagram of an environment in which a chassis may reside is illustrated in FIG. 1.2 and a diagram of a chassis is provided in FIG. 1.3.

Turning to FIG. 1.2, FIG. 1.2 shows a top view diagram of a building (115) in which chassis may reside in accordance with one or more embodiments of the invention. The building (115) may house a data center (e.g., an aggregation of information handling systems) that includes any number of information handling systems (e.g., 10A, 10B). The information handling systems include chassis which may need to intake and exhaust gases for temperature regulation purposes.

To facilitate gas management within the building (115), the information handling systems may be organized into rows (or other groupings of information handling systems). In FIG. 1.2, the rows of information handling system extend from top to bottom along the page. To enable gases to be provided to the information handling systems (e.g., for temperature regulation purposes), an airflow conditioner (120) may be disposed within the building. The airflow conditioner (120) may provide supply airflow (122) and take in a return airflow (124). These airflows are illustrated as arrows having dashed tails.

The supply airflow (122) may be at lower temperature than the return airflow (124). Consequently, when information handling systems obtain portions of the supply airflow (122), the information handling systems may be able to utilize the supply airflow (122) to cool components disposed within the chassis of the information handling systems. For example, gases from the supply airflow (122) may be passed by components disposed within chassis of information handling systems that are at elevated temperatures. The gases may be at a lower temperature than the components. Consequently, thermal exchange between the gases in the components may decrease the temperature of the components.

After utilizing the gases from the supply airflow (122), the information handling systems may exhaust the gases as the return airflow (124). After being exhausted from the information handling systems, the return airflow (124) may be obtained by the airflow conditioner (120), cooled, and recirculated as the supply airflow (122).

In addition to cooling the return airflow (124), the airflow conditioner (120) may be capable of obtaining gases from other areas (e.g., outside of the building), reducing the humidity level of an airflow, and/or otherwise conditioning gases for use by information handling systems and/or other devices.

To manage the aforementioned process, a system environmental manager (130) may be disposed within the building (115) or at other locations. The system environmental manager (130) may be a computing device programmed to (i) obtain information regarding the operation of the information handling systems and (ii) set the operating points of the airflow conditioner (120). By doing so, the system environmental manager (130) may cause the airflow conditioner (120) to provide gases to the information handling systems having a temperature and/or humidity level that may better enable the information handling systems to regulate their respective environmental conditions within the chassis of the respective information handling systems.

The airflow conditioner (120) may include functionality to granularly, or at a macro level, modify the temperature and/or humidity level of the supply airflow (122). Consequently, different information handling systems (or groups thereof) may receive different supply airflows (e.g., 122) having different characteristics (e.g., different temperatures and/or humidity levels, different sources, etc.).

Conditioning the return airflow (124) or gases obtained from outside of the building (115) may be costly, consume large amount of electricity, or may otherwise be undesirable. To reduce these costs, the system environmental manager (130) may set the operating point (e.g., desired temperature/humidity levels of different portions of the supply airflow (122)) of the airflow conditioner (120) to only provide the minimum necessary characteristics required by each of the IHSs. By doing so, the cost of providing the supply airflow (122) having characteristics required to meet the environmental requirements of the chassis of the information handling systems may be reduced.

To decide how to set the operating points of the airflow conditioner (120), the system environmental manager (130) may obtain and/or be provided information regarding the environmental conditions within each of the chassis. For example, the system environmental manager (130) may be operably connected to environmental managers of each of the chassis and/or the airflow conditioner (120) via any combination of wired and/or wireless networks. The respective environmental managers of the chassis may provide such information to the system environmental manager (130) and/or service requests regarding the operating points of the airflow conditioner (120) via the operable connections.

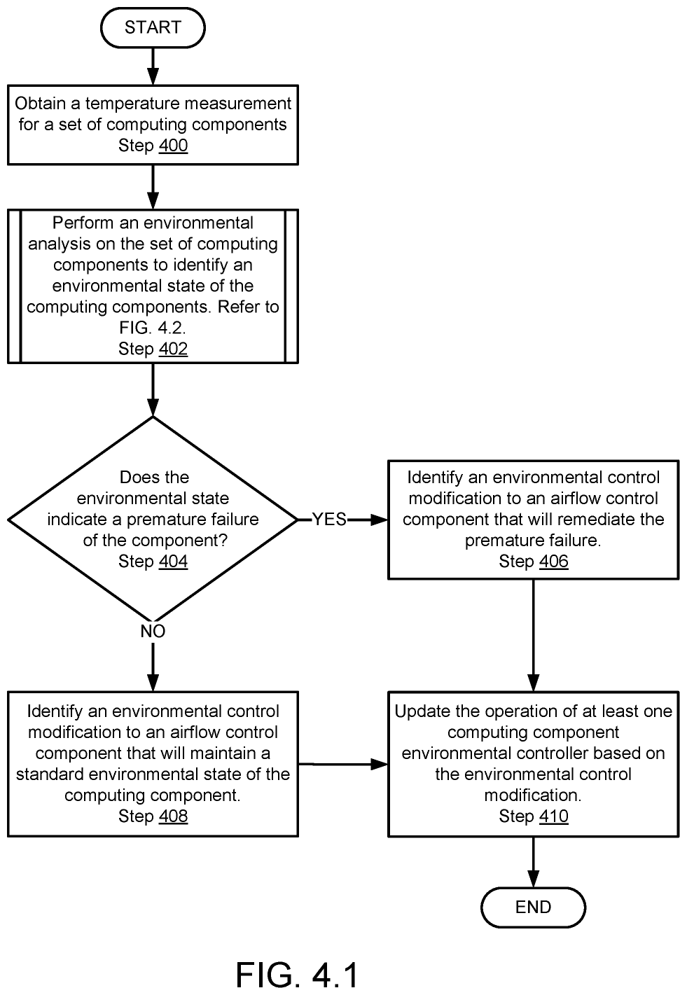

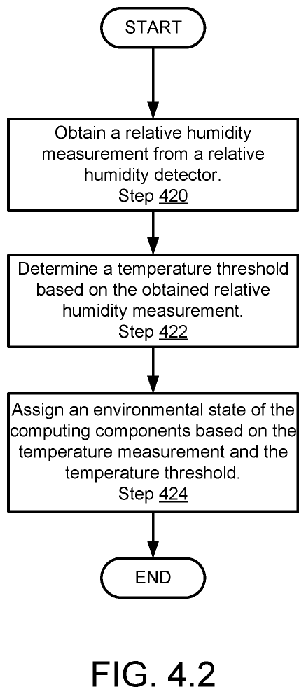

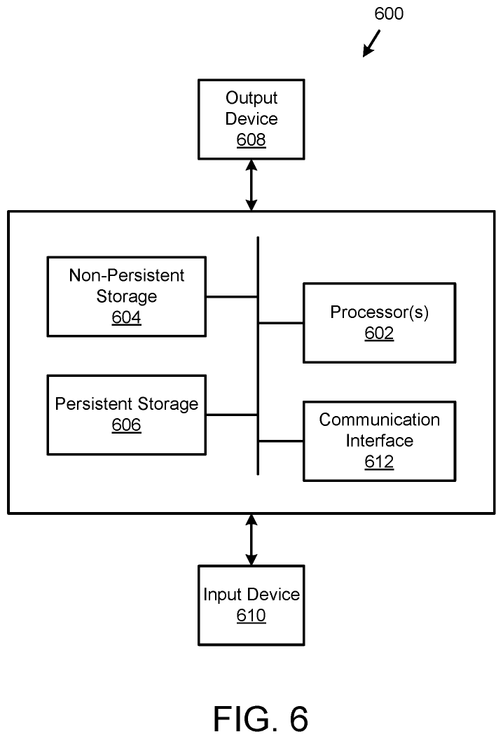

The system environmental manager (130) may be implemented using a computing device. For additional details regarding computing devices, refer to FIG. 6. The system environmental manager (130) may perform all, or a portion, of the methods illustrated in FIGS. 4.1-4.2 while providing its functionality.

Turning to FIG. 1.3, FIG. 1.3 shows a diagram of a chassis (100A) in accordance with one or more embodiments of the invention. A chassis may be a portion of an IHS and/or house all, or a portion, of an IHS. An information handling system may include a computing device that provides any number of services (e.g., computing implemented services). To provide services, the computing device may utilize computing resources provided by computing components (140). The computing components (140) may include, for example, processors, memory modules, storage devices, special purpose hardware, and/or other types of physical components that contribute to the operation of the computing device. For additional details regarding computing devices, refer to FIG. 6.

Because the computing device uses computing components (140) to provide services, the ability of the computing device to provide services is limited based on the number and/or quantity of computing devices that may be disposed within the chassis. For example, by adding additional processors, memory modules, and/or special purpose hardware devices, the computing device may be provided with additional computing resources which it may be used to provide services. Consequently, large number of computing components that each, respectively, generate heat may be disposed within the chassis.

To maintain the temperatures of the computing components (140) (and/or other types of components) within a nominal range, gases may be taken in through an air exchange (102). The gases may be passed by the computing components (140) to exchange heat with them. The heated gases may then be expelled out of another air exchange (102).

However, by taking in and expelling gases used for cooling purposes, the components disposed within the chassis (100A) may be subject to degradation due to corrosion. For example, as discussed above, the gases may include components such as humidity that may chemical react with the computing components (140) and/or other types of components disposed in the chassis (100A). The chemical reactions may damage the structure and/or change the electrical properties of the computing components (140). These changes may negatively impact the ability of the computing device to provide its functionality.

For example, the computing device may have a service life during which it is expected that the computing device will be likely to provide its functionality. However, changes in the structure and/or electrical properties of these components due to exposure to humidity or other components of the gases used for temperature regulation purposes may cause the components to prematurely fail ahead of the service life of the computing device.

In general, embodiments of the invention provide methods, devices, and systems for managing the internal environments of chassis to reduce the likelihood of premature failure of computing components (140) due to corrosion. By reducing the likelihood of the occurrence of premature failures of computing components, the computing devices disposed within the chassis (100A) may be more likely to meet their respective service life goals, have lower operation costs, and/or require fewer repairs during their respective service life. For additional details regarding the computing components (140), refer to FIG. 1.4.

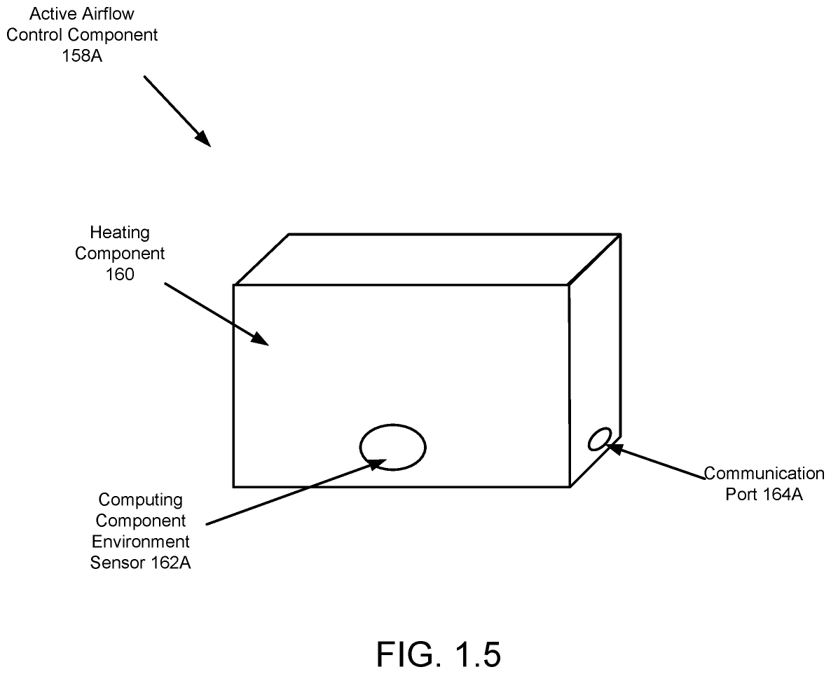

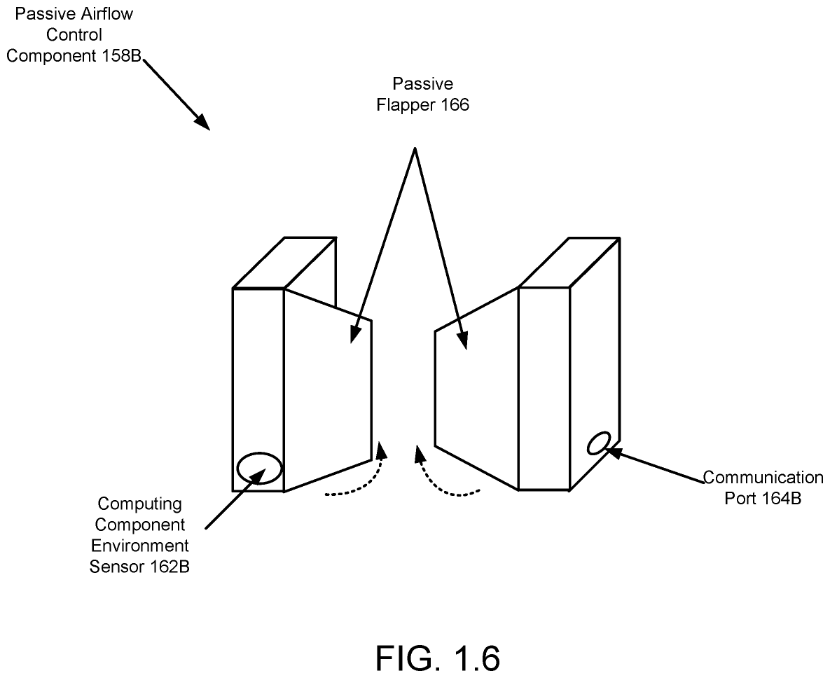

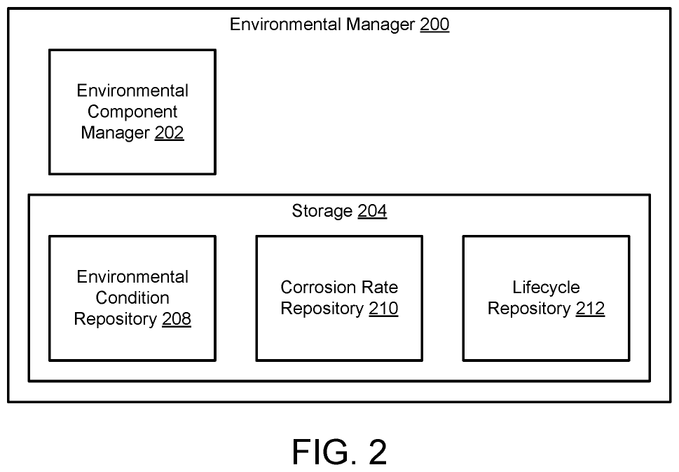

To manage the internal environment (104) of the chassis, the chassis (100A) may include a chassis environmental manager (150). The chassis environmental manager (150) may provide environmental management services. Environmental management services may include (i) obtaining information regarding the rates of corrosion occurring within the chassis, (ii) determining, based on the corrosion rates, whether the devices within the chassis are likely to meet their service life goals, and (iii) modifying the operation (e.g., modifying operating points) of environmental control components (152) and/or characteristics of gases taken into the chassis to reduce the likelihood of premature failure of components disposed within the chassis (100A) due to corrosion. For additional details regarding the chassis environmental manager (150), refer to FIG. 2.

While illustrated in FIG. 1.3 as a physical structure, as will be discussed with respect to FIG. 2, the chassis environmental manager (150) may be implemented as a logical entity (e.g., a program executing using the computing components (140)). For example, a computing device disposed in the chassis may host a program that provides the functionality of the chassis environmental manager (150).

To enable the chassis environmental manager (150) to provide its functionality, the chassis (100A) may include one or more relative humidity detectors (e.g., 154) and temperature detectors (e.g., 156). These detectors may measure the temperature and/or relative humidity of various components disposed within the chassis (100A). These detectors may be implemented as sensors or other types of physical devices that are operably connected to the chassis environmental manager (150). In some embodiments of the invention, the functionality of the temperature detectors may be provided by, in all or in part, the computing components (140). For example, the computing components (140) may include functionality to report their respective temperatures and/or temperatures of the internal environment (104) of the chassis (100A).

The chassis (100A) may also include chassis environmental control components (152). The environmental control components (152) may include physical devices that include functionality to modify characteristics (e.g., temperature, humidity level, airflow rates/directions) of the internal environment (104) at a macroscopic level. The chassis (100A) may include any number of environmental control components disposed at any number of locations within the chassis.

For example, the environmental control components (152) may include gas movers such as fans. The fans may be able to modify the rate of gases being taken into and expelled from the chassis (100A) through the air exchangers (e.g., 102). The rate of intake and exhaust of gases may cause an airflow to be generated within the internal environment (104). The airflow may be used to modify the rate of thermal exchange between the computing components (140) and the internal environment (104) (e.g., an environment proximate to the computing components (140)).

In another example, the environmental control components (152) may include heaters. The heaters may be able to modify the temperature of the internal environment (104). For example, heaters may be disposed at a front of the chassis (e.g., where gases are taken into the chassis) and/or about different locations within the chassis. These heaters may be used to generally and/or locally heat the internal environment (104). By doing so, the relative humidity level and temperature of the internal environment (104) proximate to the computing components (140) and/or different components may be controlled. The temperature and/or relative humidity level may be utilized to limit, reduce, or otherwise control corrosion rates of the computing components (140).

In another example, the environmental control components (152) may include components that are not disposed in the chassis (not shown). For example, the environmental control components may include an airflow conditioner discussed with respect to FIG. 1.2. These external components may be used in conjunction with the environment control components disposed within the chassis to manage the temperature and/or relative humidity levels throughout the internal environment (104) of the chassis.

The chassis (100A) may include any number and type of environmental control components without departing from the invention. Any of the environmental control components may be implemented using physical devices operably connected to and/or controllable by the chassis environmental manager (150) and/or a system environmental manager (e.g., 130, FIG. 1.2) (alone or in combination). Any number of chassis environmental managers and system environmental managers may cooperatively operate to control the temperature and/or relative humidity levels of the internal environments of any number of chassis to control the rate of corrosion occurring within the chassis and/or manage the thermal load generated by the computing components (140) and/or other components.

The chassis (100A) may include airflow control components (158). In one or more embodiments of the invention, the airflow control components (158) may include physical devices that include functionality to modify characteristics (e.g., temperature, humidity level, airflow rates/directions) of the ambient environment surrounding the computing components (140) at a more granular level (e.g., without modifying characteristics of other computing components in the chassis (100A)) than that of the environmental control components (152). For example, while the environmental control components (152) may increase the airflow to the internal environment (104), an airflow control component of a computing component may reduce the airflow to the ambient environment to a specific computing component(s).

In one or more embodiments of the invention, the airflow control components (158) modify the characteristics of the ambient environment surrounding the computing components (140) by reducing airflow to the computing components, producing heat that increases the temperature of the ambient environment, and/or any other mechanism that results in modification of the ambient environment without departing from the invention.

In one or more embodiments of the invention, the airflow control components (158) are implemented as passive components. A passive component may be a component that does not generate any heat to alter the ambient environment of the computing components. In other words, the passive component may redirect airflow by reacting to the characteristics of the ambient environment that result in the redirection. An airflow control component implemented as a passive component may be referred to as a passive airflow control component. For additional details regarding the passive airflow control component, refer to FIG. 1.6.

In one or more embodiments of the invention, the airflow control components (158) are implemented as active components. An active component may be a component that utilizes an active actuator to perform the modifications to the ambient environment. Examples of active actuators may include, but are not limited to: motors, heating components, secondary air movers, and/or a cooling component. An airflow control component implemented as an active component may be referred to as an active airflow control component. For additional details regarding the active airflow control component, refer to FIG. 1.5.

To cooperatively operate, the chassis environmental managers and system environmental managers may be operably connected to one another (e.g., via wired and/or wireless networks). The aforementioned components may share information with one another (e.g., detector data, operating set points of different environmental control components, etc.). These components may implement any type of model for controlling and/or delegating control of the system for temperature, relative humidity level, and/or corrosion rate management purposes. When providing their respective functionalities, these components may perform all, or a portion, of the methods illustrated in FIGS. 4.1-4.2. Any of these components may be implemented using a computing device. For additional details regarding computing devices, refer to FIG. 6.

While the chassis (100A) of FIG. 1.3 has been illustrated as including a limited number of specific components, a chassis in accordance with one or more embodiments of the invention may include additional, fewer, and/or different components without departing from the invention. Additionally, while the chassis (100A) is illustrated as having a specific form factor (e.g., rack mount), a chassis in accordance with embodiments of the invention may have different form factors without departing from the invention.

As discussed above, the chassis (100A) may house computing components (140). Turning to FIG. 1.4, FIG. 1.4 shows a diagram of computing components (140) in accordance with one or more embodiments of the invention. The computing components (140) may enable computing devices to provide services, as discussed above.

The computing components (140) may include any number of hardware devices (142). The hardware devices (142) may include, for example, packaged integrated circuits (e.g., chips). The hardware devices (142) may enable any number and type of functionalities to be performed by a computing device.

The computing components (140) may also include a circuit card (144). The circuit card (144) may enable any of the hardware devices (142) to be operably connected to one another and/or other components not illustrated in FIG. 1.4. For example, the circuit card (144) may be a multiplayer printed circuit board that includes circuitry.

The circuit card (144) may include traces (146) that electrically interconnect various hardware devices (142) to one another and/or other components not illustrated in FIG. 1.4. The traces (146) may be formed out of conductive materials such as copper thereby enabling electrical power to be provided to the hardware devices (142), electrical signals to be distributed among the hardware devices (142), etc.

Returning to the hardware devices (142), these devices may consume electrical power and generate heat as a byproduct of performing their functionality. Further, the hardware devices (142) may have some sensitivity to temperature. For example, the hardware devices (142) may only operate nominally (e.g., as designed) when the temperatures of the respective hardware devices (142) are maintained within a preferred temperature range. Consequently, all, or a portion, of the hardware devices (142) may require some level of cooling to continue to operate nominally.

As discussed above, to facilitate cooling of the hardware devices (142), airflows within the chassis may be generated by environmental control components such as fans, heaters, etc. The airflows may cause gases that are at different temperatures and/or relative humidity levels to be taken into the chassis, used for cooling purposes, and then expelled from the chassis.

However, these processes may be problematic because the gases used for cooling purposes may also contribute to corrosion being formed on, for example, the traces (146), interconnections between the traces (146) and the hardware devices (142), etc. For example, when the traces (146) are exposed to gases that include humidity, the metals of the traces (146) may react with the gases thereby forming corrosion.

The corrosion may, if kept to a low level, not impact the ability of the hardware devices (142) to perform their functionality over the course of the desired lifetime (e.g., service life) of a computing device. In contrast, if the rate of corrosion rises to a high enough level, the corrosion may negatively impact the ability of the hardware devices (142) to perform their respective functionalities to a level that causes the computing device to fail. Consequently, the computing device and corresponding IHS may fail prior to it meeting its desired service life due to corrosion.

For example, if an IHS has a desired service life of 5 years, corrosion may cause one of the traces (146) to fail prior to 5 years of service thereby causing the IHS to prematurely fail.

While the computing components (140) are illustrated in FIG. 1.4 as including specific numbers and specific types of components, computing components in accordance with one or more embodiments of the invention may include additional, different, and/or fewer components without departing from the invention.

To manage an ambient environment of a computing component, a chassis in accordance with embodiments of the invention may include an active airflow control component. FIG. 1.5 shows a diagram of an exemplary active airflow control component (158A) in accordance with one or more embodiments of the invention. The active airflow control component (158A) may be an embodiment of the airflow control component (158, FIG. 1.3) discussed above.

The active airflow control component (158A) may be a physical device that is able to, at a granular level, modify characteristics of the ambient environment of a set of one or more computing components without affecting the ambient environment of other computing components outside of the set. The active airflow control component (158A) may include an active component that modifies the characteristics of the ambient environment by increasing (or decreasing) the temperature of a heating component (160) that produces heat that modifies the temperature of the aforementioned ambient environment. The heating component (160) may be increased by, for example, applying a high current along the material of the heating component (160) until the heating component (160) increases to a desired temperature.

The active airflow control component (158A) may utilize a communication port (164A) that communicates with a chassis environmental manager (e.g., 150, FIG. 1.3) and/or with a system environmental manager (e.g., 130, FIG. 1.2) to determine when to apply the increase in temperature to the heating component (160). The active airflow control component (158A) obtains signals (e.g., electrical signals) from the system environmental manager or the chassis environmental manager that result in increasing or decreasing the heat applied to the heating component (160). The signals may be obtained from any other entity without departing from the invention.

The active airflow control component (158A) may further include a computing component environment sensor(s) (162A). The computing component environment sensor (162A) may be a device that includes functionality for measuring characteristics of the set of computing components (or of the ambient environment surrounding the set of computing components) associated with the active airflow control component (158A). The computing component environment sensor may measure, for example, a temperature of the ambient environment, a relative humidity level of the ambient environment, a rate of corrosion of a portion of the active airflow control component (158A) (which may be used to estimate the rate of corrosion of portions of a computing component in the set), and/or any combination thereof. The computing component environment sensor (162A) may measure any other characteristics without departing from the invention. Measurements obtained by the computing component environment sensor (162A) may be transmitted to the system environmental manager, the chassis environmental manager, and/or any other entity without departing from the invention.

In one or more embodiments of the invention, the computing component environment sensor (162A) includes functionality for measuring the rate of corrosion using a sensing loop (not shown) that varies in resistivity as the sensing loop undergoes corrosion. The resistivity may be used to estimate the rate of corrosion of the computing components due to the similarity of ambient environment of the active airflow control component (158A) and the set of computing components.

In one or more embodiments of the invention, the computing component environment sensor (162A) includes functionality for measuring the temperature of the ambient environment of the computing components. For example, the computing component environment sensor (162A) may include temperature-sensitive material that changes in resistivity as the temperature changes.

In one or more embodiments of the invention, the computing component environment sensor (162A) includes functionality for measuring the relative humidity of the ambient environment of the computing components. For example, the computing component environment sensor (162A) may include applying a current to a humidity-sensitive portion of material using two electrodes and measuring the resistivity of the humidity-sensitive material based on the applied current.

While the active airflow control component (158A) in FIG. 1.5 has been illustrated and described as using resistive detection modalities, other testing modalities may be employed without departing from the invention. For example, the changes in capacitive or inductive characteristics of arrangements of a material subject to corrosion, temperature, or relative humidity may be used to ascertain the quantity of corrosion that has occurred.

To ascertain the rates of corrosion that are occurring, the aggregate amount of corrosion that has occurred at different points in time may be used to calculate a rate of change of corrosion.

While the active airflow control component (158A) has been illustrated in FIG. 1.5 as including specific numbers and types of components, an active airflow control component (158A) in accordance with embodiments of the invention may include different, fewer, and/or additional components without departing from the invention.

To manage an ambient environment of a set of one or more computing components, a chassis in accordance with embodiments of the invention may include a passive airflow control component. FIG. 1.6 shows a diagram of an exemplary passive airflow control component (158B) in accordance with one or more embodiments of the invention. The passive airflow control component (158B) may be an embodiment of the airflow control component (158, FIG. 1.3) discussed above.

The passive airflow control component (158B) may be a physical device that is able to, at a granular level, modify characteristics of the ambient environment of a set of one or more computing components without affecting the ambient environment of other computing components outside of the set. The passive airflow control component (158B) may be modified in response to a change in ambient environment to enable, or disable, airflow to pass through the set of computing components associated with the passive airflow control component (158B). The airflow may be an airflow provided by an air mover (e.g., a fan) in the chassis. In enabling, or disabling, the airflow, the temperature of the ambient environment of the set of computing components may be increased or decreased, which may result in a reduction in the rate of change of corrosion on the set of computing components while maintaining the nominal range of temperature that is preferred for operability in the set of computing components.

The passive airflow control component (158B) may utilize a communication port (164B) to communicate with other entities. The communication port (164B) may include functionality similar to that of the communication port (162A, FIG. 1.5) discussed above.

The passive airflow control component (158B) may further utilize a computing component environment sensor(s) (162B). The computing component environment sensor (162B) may include functionality similar to that of the computing component environment sensor (162A, FIG. 1.5) discussed above.

In one or more embodiments if the invention, the computing passive airflow control component (158B) includes a passive flapper (166). The passive flapper (166) is a device that is modified to modify the airflow proximate to the set of computing components. For example, the passive flapper (166) may perform a motion that blocks the airflow from reaching the set of computing components when the computing component environment sensor (162B) detects a temperature below a predetermined threshold.

While the passive flapper (166) may modify the airflow proximate to the set of computing devices, the airflow proximate to a second set of computing devices in the chassis may not be modified as a result of the modification to the airflow proximate to the first set of computing components. For example, the second set of computing components may be associated with a second passive flapper that modifies the airflow proximate to the second set of computing components without modifying the airflow proximate to the first set of computing components.

In one or more embodiments of the invention, the passive flapper is implemented as a shape memory alloy. The shape memory alloy may be a material that deforms in shape based on a change in temperature. For example, the shape memory alloy may expand when the temperature drops below a temperature threshold. The shape memory alloy may be designed based on the desired temperature threshold. By expanding in shape, the shape memory alloy may block the airflow from reaching the set of computing components. The shape memory alloy may return to a pre-deformed shape as the temperature rises over a second temperature threshold. The second temperature threshold may be different or similar to the first temperature threshold.

In one or more embodiments of the invention, the passive flapper (166) is implemented using a computer (or another processing component) that operates a valve that opens and/or closes in response to a signal obtained using the communication port (164B). The valve may move to close the airflow when the temperature drops to a first temperature threshold and open when the temperature rises to a second temperature threshold. The opening and closing of the valve may be determined by the system environmental manager, the chassis environmental manager, and/or any other entity in accordance with the method of FIGS. 4.1 and 4.2. The opening and closing may be determined using any other method without departing from the invention.

While the passive airflow control component (158B) has been illustrated in FIG. 1.6 as including specific numbers and types of components, a passive airflow control component (158B) in accordance with embodiments of the invention may include different, fewer, and/or additional components without departing from the invention.

To reduce the likelihood of premature failure of IHSs, an IHS in accordance with embodiments of the invention may include an environmental manager. Turning to FIG. 2, FIG. 2 shows a diagram of an environmental manager (200) in accordance with one or more embodiments of the invention. The system environmental manager (130) and/or chassis environmental manager (150) illustrated in FIGS. 1.2 and 1.3, respectively, may be similar to the environmental manager (200).

As discussed above, the environmental manager (200) may provide environmental management services. Environmental management services may reduce the likelihood that IHSs fail prematurely (e.g., prior to meeting service life goals) due to corrosion of components of the IHSs.

In one or more embodiments of the invention, the environmental manager (200) is implemented using computing devices. The computing devices may be, for example, mobile phones, tablet computers, laptop computers, desktop computers, servers, distributed computing systems, embedded computing devices, or a cloud resource. The computing devices may include one or more processors, memory (e.g., random access memory), and persistent storage (e.g., disk drives, solid state drives, etc.). The persistent storage may store computer instructions, e.g., computer code, that (when executed by the processor(s) of the computing device) cause the computing device to provide the functionality of the environmental manager (200) described through this application and all, or a portion, of the methods illustrated in FIGS. 4.1-4.2. The environmental manager (200) may be implemented using other types of computing devices without departing from the invention. For additional details regarding computing devices, refer to FIG. 6.

In one or more embodiments of the invention, the environmental manager (200) is implemented using distributed computing devices. As used herein, a distributed computing device refers to functionality provided by a logical device that utilizes the computing resources of one or more separate and/or distinct computing devices. For example, in one or more embodiments of the invention, the environmental manager (200) is implemented using distributed devices that include components distributed across any number of separate and/or distinct computing devices. In such a scenario, the functionality of the environmental manager (200) may be performed by multiple, different computing devices without departing from the invention.

To provide environmental management services, the environmental manager (200) may include an environmental component manager (202) and a storage (204). Each of these components is discussed below.

The environmental component manager (202) may manage the components of the chassis and/or other components that may be used to control the characteristics (e.g., temperature, humidity level, airflow rates, etc.) of the internal environment of the chassis and/or of the ambient environment of one or more sets of computing components. To manage them, the environmental component manager (202) may (i) obtain information regarding the environmental conditions within the chassis including temperatures and corrosion rates, (ii) determine, using the environmental information, whether the IHS is likely to prematurely fail, and (iii) if the IHS is unlikely to meet its service life goals due to premature failure, modify the characteristics of the internal environment of the chassis to improve the likelihood that the IHS will meet its service life goals.

To obtain information regarding the environmental conditions, the environmental component manager (202) may request such information from computing components (e.g., temperatures), sensors (e.g., computing component environment sensors), and/or other types of devices (e.g., components external to the chassis). In response, the aforementioned components may provide the requested information to the environmental component manager (202). The environmental component manager (202) may store the aforementioned information as part of an environmental condition repository (208).

To ascertain whether an IHS is likely to prematurely fail due to corrosion, the environmental component manager (202) may determine a total amount of corrosion that has likely occurred, estimate the rate that will occur in the future, and use the previous amount and current rate to determine whether the computing device is likely to prematurely fail. To make this determination, the environmental component manager (202) may utilize a lifecycle repository (212). The lifecycle repository (212) may specify information that may be used to ascertain whether a premature failure will occur based on corrosion. For example, the lifecycle repository (212) may specify a total amount of corrosion that will cause various components of a computing device to fail. Based on this aggregate amount and the corrosion rate, the environmental component manager (202) may ascertain whether the amount of corrosion specified by the lifecycle repository (212) will be exceeded prior to the occurrence of the service life of the IHS.

If it is determined that the IHS will prematurely fail, the environmental component manager (202) may modify the operation of one or more environmental control components to reduce the corrosion rate within the chassis. For example, the environmental component manager (202) may increase the ambient temperature within the chassis, decrease the relative humidity level, modify airflow rates within the chassis, and/or otherwise modify the internal environment of the chassis to reduce the rate that corrosion occurs in the chassis. By doing so, the point in time at which the IHS is likely to fail due to corrosion may be pushed into the future thereby reducing the likelihood that the IHS will prematurely fail ahead of its service life being completed.

When providing its functionality, the environmental component manager (202) may utilize the storage (204) by storing and using previously stored data structures.

To provide the above noted functionality of the environmental component manager (202), the environmental component manager (202) may perform all, or a portion, of the methods illustrated in FIGS. 4.1-4.2.

In one or more embodiments of the invention, the environmental component manager (202) is implemented using a hardware device including circuitry. The environmental component manager (202) may be implemented using, for example, a digital signal processor, a field programmable gate array, or an application specific integrated circuit. The environmental component manager (202) may be implemented using other types of hardware devices without departing from the invention.

In one or more embodiments of the invention, the environmental component manager (202) is implemented using computing code stored on a persistent storage that when executed by a processor performs all, or a portion, of the functionality of the environmental component manager (202). The processor may be a hardware processor including circuitry such as, for example, a central processing unit or a microcontroller. The processor may be other types of hardware devices for processing digital information without departing from the invention.

In one or more embodiments disclosed herein, the storage (204) is implemented using devices that provide data storage services (e.g., storing data and providing copies of previously stored data). The devices that provide data storage services may include hardware devices and/or logical devices. For example, storage (204) may include any quantity and/or combination of memory devices (i.e., volatile storage), long term storage devices (i.e., persistent storage), other types of hardware devices that may provide short term and/or long term data storage services, and/or logical storage devices (e.g., virtual persistent storage/virtual volatile storage).

For example, storage (204) may include a memory device (e.g., a dual in line memory device) in which data is stored and from which copies of previously stored data are provided. In another example, storage (204) may include a persistent storage device (e.g., a solid state disk drive) in which data is stored and from which copies of previously stored data are provided. In another example, storage (204) may include (i) a memory device (e.g., a dual in line memory device) in which data is stored and from which copies of previously stored data are provided and (ii) a persistent storage device that stores a copy of the data stored in the memory device (e.g., to provide a copy of the data in the event that power loss or other issues with the memory device that may impact its ability to maintain the copy of the data cause the memory device to lose the data).

The storage (204) may store data structures including an environmental condition repository (208), a corrosion rate repository (210), and a lifecycle repository (212). Each of these data structures is discussed below.

The environmental condition repository (208) may include one or more data structures that include information regarding the environmental conditions within a chassis. For example, when temperature and/or corrosion data is read from a detector, the read information may be stored in the environmental condition repository (208). Consequently, a historical record of the environmental conditions in the repository may be maintained.

In some embodiments of the invention, the environmental condition repository (208) may only include the most up to date information regarding the environmental conditions within the chassis. For example, only the most recent detector readings may be stored in the environmental condition repository (208).

The environmental condition repository (208) may include any type and quantity of information regarding the environmental conditions within the repository. For example, the environmental condition repository (208) may include temperature sensor data from discrete temperature sensors and/or temperature sensors integrated into computing components (and/or other types of devices). In another example, the environmental condition repository (208) may include corrosion rates from discrete or integrated corrosion detectors (e.g., on board a circuit card). In another example, the environmental condition repository (208) may include airflow rate data regarding the flow of gases within a chassis.

In addition to the sensor data, the environmental condition repository (208) may include spatial data regarding the relative locations of components within a chassis. For example, some components may be disposed away from corrosion detectors. Consequently, it may not be possible to directly measure the temperature and/or corrosion of such components. The spatial data may be used to estimate, using measured temperatures and/or corrosion, the likely corrosion rates of the components.

The corrosion rate repository (210) may include one or more data structures that include information regarding the rates at which components disposed in the chassis have corroded. For example, the corrosion rate repository (210) may include tables associated with different components disposed within the chassis. Each of these tables may include the measured and/or estimated corrosion of the components.

The tables may also include the time at which the corrosion was measured. Consequently, the rates of corrosion of the components may be ascertained using the information included in the tables (e.g., corrosion at time T1−corrosion at time T2/the difference between T1 and T2).

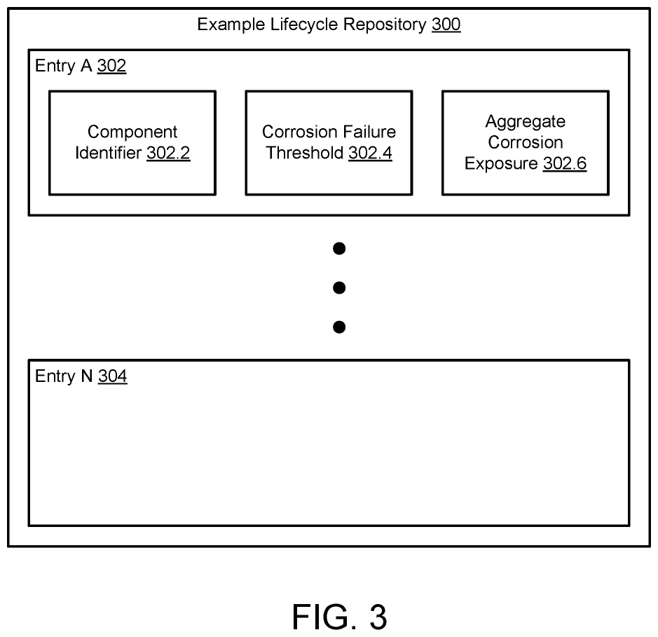

The lifecycle repository (212) may include one or more data structures that include information regarding the desired life of components disposed in a chassis of an information handling system. For example, the lifecycle repository (212) may specify how much corrosion may occur with respect to different components before the respective components are likely to fail. The aforementioned information may be used in conjunction with determined corrosion rates and quantities of corrosion included in the corrosion rate repository (210) to determine whether it is likely that a component, computing device, and/or IHS is likely to fail prior to its desired service life. For additional details regarding the lifecycle repository (212), refer to FIG. 3.

While the data structures stored in storage (204) have been described as including a limited amount of specific information, any of the data structures stored in storage (204) may include additional, less, and/or different information without departing from the embodiments disclosed herein. Further, the aforementioned data structures may be combined, subdivided into any number of data structures, may be stored in other locations (e.g., in a storage hosted by another device), and/or spanned across any number of devices without departing from the embodiments disclosed herein. Any of these data structures may be implemented using, for example, lists, tables, linked lists, databases, or any other type of data structures usable for storage of the aforementioned information.

While the environmental manager (200) of FIG. 2 has been described and illustrated as including a limited number of specific components for the sake of brevity, an environmental manager in accordance with embodiments of the invention may include additional, fewer, and/or different components than those illustrated in FIG. 2 without departing from the invention.

Further, any of the components may be implemented as a service spanning multiple devices. For example, multiple computing devices housed in multiple chassis may each run respective instances of the environmental component manager (202). Each of these instances may communicate and cooperate to provide the functionality of the environmental component manager (202).

As discussed above, the environmental manager (200) may utilize a lifecycle repository when performing its functionality. FIG. 3 shows a diagram of an example lifecycle repository (300) that may be used by the environmental manager (200) when providing its functionality.

In one or more embodiments of the invention, the example lifecycle repository (300) includes any number of entries (e.g., 302, 304). Each of the entries may include a component identifier (302.2), corrosion failure threshold (302.4), and aggregate corrosion exposure (302.6).

The component identifier (302.2) may be an identifier of a component associated with the entry. In other words, the component associated with the data included in the entry.

The corrosion failure threshold (302.4) may specify a quantity of corrosion that, if exceeded, is likely to result in a failure of the component corresponding to the component identified by the component identifier (302.2).

The aggregate corrosion exposure (302.6) may specify the amount of corrosion that is estimated to have occurred to the component identified by the component identifier (302.2). For example, whenever the amount of corrosion is measured by a corrosion detector, the aggregate corrosion exposure (302.6) reflects the amount that is estimated to have occurred to the component identified by the component identifier (302.2).

The estimate may be made based on, for example, the relative location of the component with respect to the corrosion detector, a temperature differential that may exist between the corrosion detector and the component, and/or other factors that may cause the amount of measured corrosion of the corrosion detector to be different from that which the component is likely to have suffered. For example, differences in temperatures, materials, and/or other factors may cause the component to have an increased or decreased level of corrosion when compared to that measured by a corrosion detector. The aggregate corrosion exposure (302.6) may reflect that difference when compared to the amount of corrosion specified by the corrosion rate repository (210).

While the example lifecycle repository (300) has been described as including a limited amount of specific information, the example lifecycle repository (300) may include additional, less, and/or different information without departing from the embodiments disclosed herein. Further, the example lifecycle repository (300) may be combined, subdivided into any number of data structures, may be stored in other locations (e.g., in a storage hosted by another device), and/or spanned across any number of devices without departing from the embodiments disclosed herein. Additionally, while described as being implemented using a list of entries (302, 304), the example lifecycle repository (300) may be implemented using different types of data structures (e.g., databases, linked lists, tables, etc.) without departing from the invention.

Returning to FIG. 2, the environmental manager (200) may provide environmental services. FIGS. 4.1-4.2 illustrate methods that may be performed by the environmental manager (200) of FIG. 2 when providing environmental management services.

FIG. 4.1 shows a flowchart of a method in accordance with one or more embodiments of the invention. The method depicted in FIG. 4.1 may be used to manage the internal environment of a chassis in accordance with one or more embodiments of the invention. The method shown in FIG. 4.1 may be performed by, for example, an environmental manager (e.g., 200, FIG. 2). Other components of the system illustrated in FIGS. 1.1-1.6 may perform all, or a portion, of the method of FIG. 4.1 without departing from the invention.

While FIG. 4.1 is illustrated as a series of steps, any of the steps may be omitted, performed in a different order, additional steps may be included, and/or any or all of the steps may be performed in a parallel and/or partially overlapping manner without departing from the invention.

In step 400, a temperature measurement is obtained for a set of computing components. The computing component may be a computing component disposed in a chassis. The temperature measurement may be obtained from a computing component environment sensor of an airflow control component of the set of computing components.

In step 402, an environmental analysis is performed on the set of computing components to identify an environmental state of the set. In one or more embodiments of the invention, the environmental analysis includes obtaining a relative humidity measurement, determining a temperature threshold based on the relative humidity measurement, and assigning an environmental state of the set of computing components based on whether the temperature measurement is below the temperature threshold.

In one or more embodiments of the invention, the environmental analysis is performed via the method illustrated in FIG. 4.2 (described below). The environmental analysis may be performed via any other method without departing from the invention.

In step 404, it is determined whether the environmental state indicates a premature failure of the component. The determination may be made by using the environmental state to determine whether the component is likely to prematurely fail before the service life of the set of computing components is met. For example, the environmental state may specify a corrosive-prone state. The corrosive prone state may indicate a premature failure of the set of computing components.

If it is determined that the environmental state indicates a premature failure of the component, the method may proceed to step 406. If it is determined that the environmental state does not indicate premature failure of the component, the method may proceed to step 408.

In step 406, an environmental control modification that will remediate the premature failure is identified. The environmental control modification may be a change in the operation of one or more airflow control components.

For example, the environmental control modification may include closing a valve of a passive airflow control component. The closing of the valve may result in airflow being blocked, or at least significantly reduced, from reaching the set of computing components. This may result in an increase in temperature in the computing components and a decrease in reactive chemicals settling on the corrosive sensitive material from the moisture in the ambient environment.

The method may proceed to step 410 following step 406.

Returning to step 404, the method may proceed to step 408 when the environmental state does not indicate a premature failure of the component.

In step 408, an environmental control modification to the airflow control component that will maintain a standard environmental state is determined.

The identified environmental control modification that maintains the standard environmental state may be based on the current state of the airflow control component. For example, the airflow control component may be in a state that enables the airflow to reach the set of computing components. In such example, the identified environmental control modification may specify not modifying the airflow control component.

In a second example, the airflow control component may be in a state that disables the airflow from reaching the computing components. Because it is determined in step 404 that the environmental state does not indicate a premature failure, the identified environmental control modification may specify modifying the airflow control component to enable airflow to reach the set of computing components. The result may be an increase in risk of a potential corrosion. However, because it was determined that the environmental state does not indicate a premature failure of the component is likely to occur, the rate of corrosion may be allowed to increase without negatively impacting the ability of the information handling system to meet its service life goal.

The method may proceed to step 410 following step 408. The method may end following step 410.

In step 410, the operation of at least one environmental control component is updated based on the environmental control modification. For example, the operating point of the at least one environmental control component may be updated to cause the environmental control modification determined in step 406 or step 408 to be implemented.

The method may end following step 410.

Using the method illustrated in FIG. 4.1, a system in accordance with embodiments of the invention may prevent premature failures due to corrosion of components of an information handling system.

FIG. 4.2 shows a flowchart of a method in accordance with one or more embodiments of the invention. The method depicted in FIG. 4.2 may be used to perform an environmental analysis on a set of computing components in accordance with one or more embodiments of the invention. The method shown in FIG. 4.2 may be performed by, for example, an environmental manager (e.g., 200, FIG. 2). Other components of the system illustrated in FIGS. 1.1-1.6 may perform all, or a portion, of the method of FIG. 4.2 without departing from the invention.

While FIG. 4.2 is illustrated as a series of steps, any of the steps may be omitted, performed in a different order, additional steps may be included, and/or any or all of the steps may be performed in a parallel and/or partially overlapping manner without departing from the invention.

In step 420, a relative humidity measurement is obtained. The relative humidity measurement may be obtained from a relative humidity detector in the chassis. Alternatively, the relative humidity measurement may be obtained from a computing component environment sensor of the airflow control component.

In step 422, a temperature threshold is determined based on the relative humidity measurement. The relative humidity measurement may affect the temperature threshold that is to be used to determine the temperature threshold in which a risk of corrosion is high. For example, a high relative humidity measurement may indicate an increased likelihood for risk of corrosion. As such, the temperature threshold may be determined to be high relative to a temperature threshold determined for a low relative humidity measurement.

In step 424, an environmental state of the computing components is assigned based on the temperature measurement and the temperature threshold. The temperature measurement is the temperature measurement obtained in step 400 of FIG. 4.1. The environmental state is assigned by comparing the temperature measurement to the determined temperature threshold and determining whether the temperature is below the temperature threshold. If the temperature is not below the temperature threshold, the environmental state may specify a standard environmental state. The standard environmental state may be associated with a lack of risk of corrosion. In other words, the standard environmental state does not indicate a premature failure of the component is likely to occur.

The method may end following step 424.

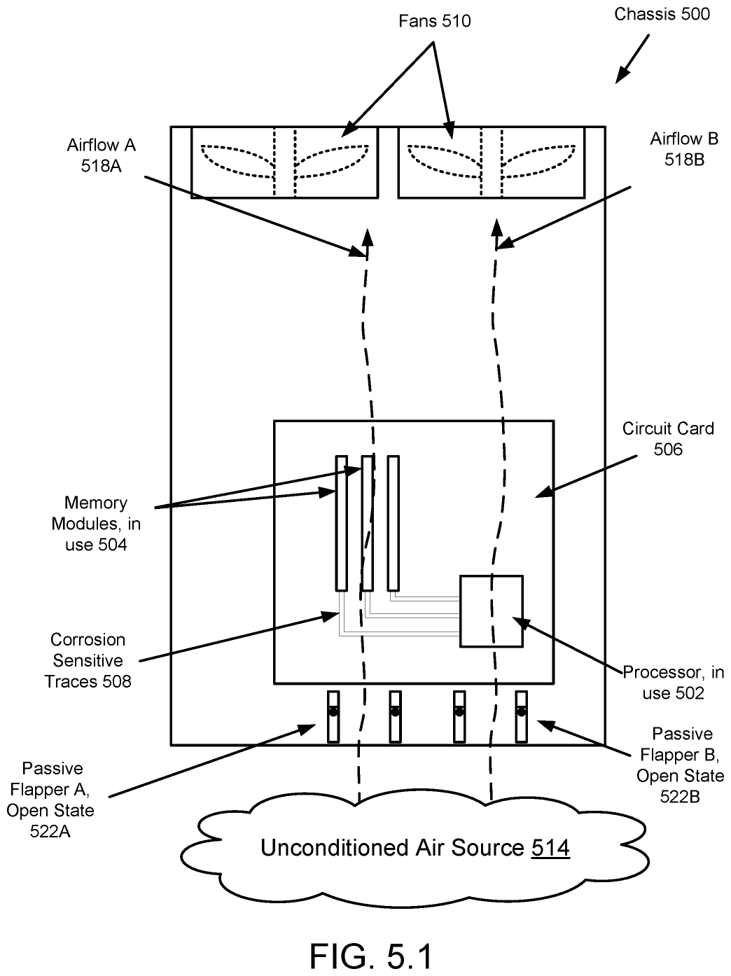

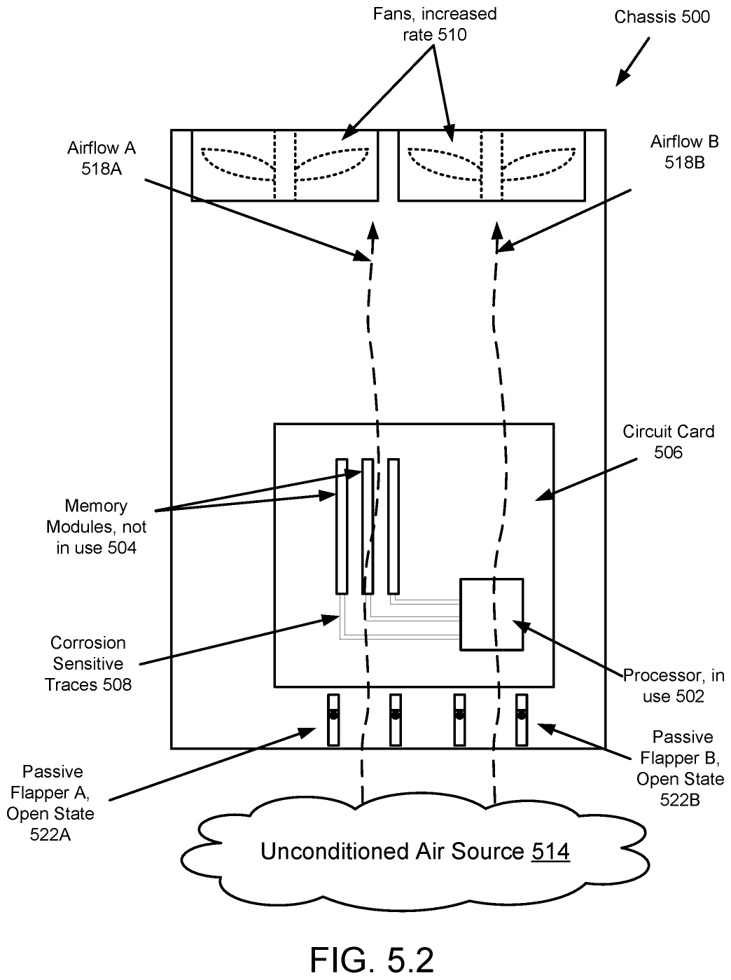

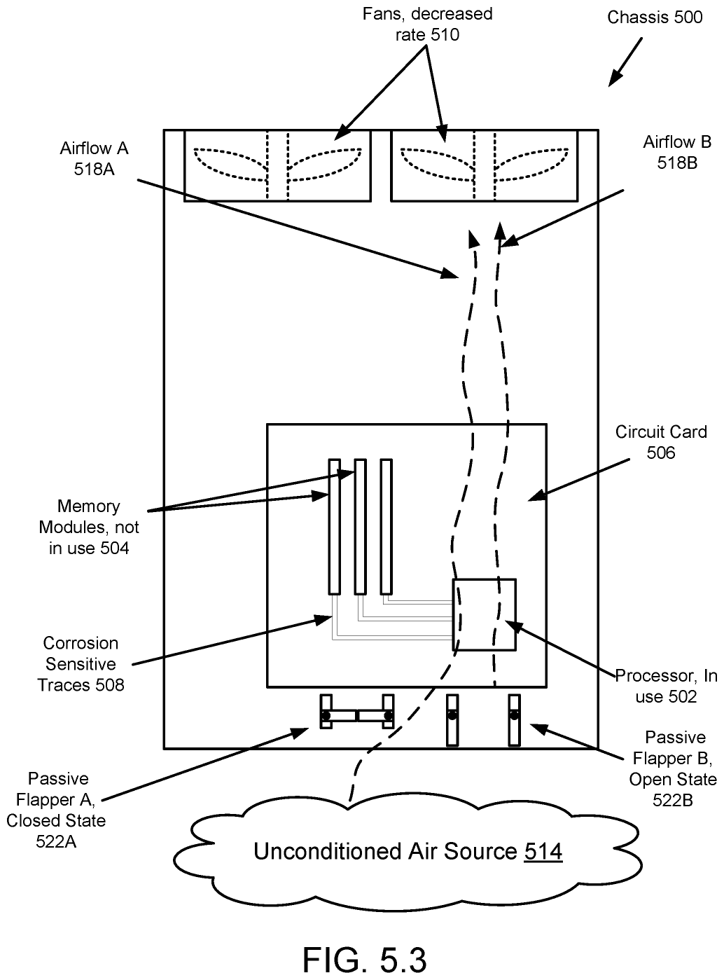

To further clarify embodiments of the invention, a non-limiting example is provided in FIGS. 5.1-5.3. FIGS. 5.1-5.3 illustrate top view diagrams of a chassis (500) of an information handling system as its operation is changed over time in accordance with one or more embodiments of the invention. For the sake of brevity, only a limited number of components of the system of FIGS. 1.1-1.6 are illustrated in each of FIGS. 5.1-5.3.

Example

Consider a scenario as illustrated in FIG. 5.1 in which a chassis (500) of an information handling system houses a set of computing components. The computing components may include, for example, a processor (502), memory modules (504), and a circuit card (506). The circuit card (506) may include corrosion sensitive traces (508). Specifically, the traces may be susceptible to corrosion when the relative humidity level reaches or exceeds 55% and the temperature drops below 65° F. For example, the traces may be formed from copper that may form oxides or other compounds when exposed to gases that include a relative humidity level that exceeds 55% and the temperature drops below 65° F.

To provide their functionalities, the processor (502) and the memory modules (504) may each consume electricity and produce heat as a byproduct during operation. Consequently, if left unchecked, the heat produced by these components may increase the temperatures of these components outside of their nominal operating ranges.

To manage the temperatures of these components, the chassis (500) may include fans (510). The fans (510) may have an adjustable rotation rate that enables them to produce airflows (e.g., 518A, 518B) of variable-rate. The operation of the fans (510) may be controlled by an environmental manager (not shown). Airflow A (518A), as it traverses proximate to the memory modules (504), reduces the temperature of the memory modules to a nominal range. Airflow B (518B), as it traverses proximate to the processor (502), reduces the temperature of the processor to another nominal range.

A first passive flapper (e.g., passive flapper A (522A)) may modulate the airflow proximate to the memory modules and corrosion sensitive traces by selectively preventing the airflow A (518A) from traversing proximate to these components. When in an open state, passive flapper A (522A) enables airflow A (518A) to traverse proximate to the memory modules (504) and passive flapper B (522B), also when in an open state, enables airflow B (518A) to traverse proximate to the processor (502).

If the processor (502) and/or the memory modules (504) are not in use, the temperature within the chassis and proximate to the corrosion sensitive traces (508) may drop below the corrosion threshold temperature of 65° F. due to thermal exchange with gases from the unconditioned air source (514). Consequently, the corrosion sensitive traces (508) and/or the memory modules may be susceptible to corrosion if the memory modules (504) are not used.

The airflows (518A, 518B) may cause gases from an unconditioned air source (514) to flow into the chassis (500), pass by the computing components (e.g., the memory modules (504), the corrosion sensitive traces (508), and the processor (502)), and then exit the rear of the chassis as illustrated by the arrow having dashed tails.

Due to the presence of the water vapor in the airflow A (518A), the corrosion sensitive traces (508) may corrode. Consequently, if the quantity of water vapor in airflow A (518A) in conjunction with the temperature proximate to the corrosion sensitive traces falls below a predetermined amount, the corrosion sensitive traces may corrode at unacceptably high rates and cause the traces to fail prior to the occurrence of the end of the service life of the computing components disposed in chassis (500).

To mitigate this potential risk, the passive flappers may each include a quantity of temperature sensitive alloy that causes the flappers to change shape when transitioning between two different temperature ranges. Specifically, the temperature sensitive alloy may cause the flappers to open when the ambient temperature is above 65 degrees and to close when the ambient temperature is below 65 degrees Fahrenheit.

For example, consider that, at a first point in time in which the processor (502) and the memory modules (504) are in use, the temperature of the computing components is 75° F. In this example, both of the passive flappers will be in the open state as illustrated in FIG. 5.1. By doing so, the airflows (518A, 518B) may both pass proximately to these components resulting in a high level of cooling provided by the airflows.

Now consider that a second point in time, illustrated in FIG. 5.2, during which the processor (502) continues to be in use, but the operation does not require any memory usage. Consequently, the ambient temperature proximate to passive flapper A (522A) may fall below 65° F. while the ambient temperature proximate to passive flapper B (522B) may stay above 65° F. due to the respective quantities of heat generated by the memory modules (low heat generation) and processor (high heat generation). In such a scenario, the shape memory allow included in passive flapper A (522A) may undergo a state transition which may cause the shape memory alloy to reshape itself, as shown in FIG. 5.3.

Turning to FIG. 5.3, the shape memory of passive flapper A (522A) has reshaped itself thereby causing the flappers on the passive flappers to close thereby entering passive flapper A (522A) into a closed state. In contrast, because the ambient temperature proximate to passive flapper B (522B) has not caused its shape memory alloy to undergo a state transition, passive flapper B (522B) has remained in a closed state.

Due to the state change of passive flapper A (522A), airflow A (518A) has been deflected away from both the corrosion sensitive traces (508) and the memory modules (504). Consequently, the cooling of these components is greatly reduced. Accordingly, the temperatures of these components rise due to the heat generated by the memory modules (504) even when they are not in use. Consequently, the rate of corrosion of the corrosion sensitive traces (508) is reduced as their temperature increases. Accordingly, the corrosion sensitive traces (508) do not prematurely fail.

End of Example

Any of the components of FIGS. 1.1-1.6 may be implemented as distributed computing devices. As used herein, a distributed computing device refers to functionality provided by a logical device that utilizes the computing resources of one or more separate and/or distinct computing devices.

Additionally, as discussed above, embodiments of the invention may be implemented using a computing device. FIG. 6 shows a diagram of a computing device in accordance with one or more embodiments of the invention. The computing device (600) may include one or more computer processors (602), non-persistent storage (604) (e.g., volatile memory, such as random access memory (RAM), cache memory), persistent storage (606) (e.g., a hard disk, an optical drive such as a compact disk (CD) drive or digital versatile disk (DVD) drive, a flash memory, etc.), a communication interface (612) (e.g., Bluetooth interface, infrared interface, network interface, optical interface, etc.), input devices (610), output devices (608), and numerous other elements (not shown) and functionalities. Each of these components is described below.

In one embodiment of the invention, the computer processor(s) (602) may be an integrated circuit for processing instructions. For example, the computer processor(s) may be one or more cores or micro-cores of a processor. The computing device (600) may also include one or more input devices (610), such as a touchscreen, keyboard, mouse, microphone, touchpad, electronic pen, or any other type of input device. Further, the communication interface (612) may include an integrated circuit for connecting the computing device (600) to a network (not shown) (e.g., a local area network (LAN), a wide area network (WAN) such as the Internet, mobile network, or any other type of network) and/or to another device, such as another computing device.

In one embodiment of the invention, the computing device (600) may include one or more output devices (608), such as a screen (e.g., a liquid crystal display (LCD), a plasma display, touchscreen, cathode ray tube (CRT) monitor, projector, or other display device), a printer, external storage, or any other output device. One or more of the output devices may be the same or different from the input device(s). The input and output device(s) may be locally or remotely connected to the computer processor(s) (602), non-persistent storage (604), and persistent storage (606). Many different types of computing devices exist, and the aforementioned input and output device(s) may take other forms.

Embodiments of the invention may provide an improved method for managing components of an information handling system. Specifically, embodiments of the invention may provide a method and device for managing an environment in which components of an IHS may reside. To do so, embodiments of the invention may manage the environment based on the risk of corrosion and temperature sensitivities. By doing so, premature failures due to corrosion and temperature may be reduced. To ascertain these risks, an airflow control component may be used to monitor the temperature and/or relative humidity of a set of computing components and control the airflow provided to the set. This monitoring and controlling may prevent condensation of moisture that may include reactive chemicals from causing corrosion to corrosion sensitive materials in the set of computing components.

Thus, embodiments of the invention may address the problem of environments that may cause premature failures of devices due to corrosion. Specifically, embodiments of the invention may provide a method of managing both the temperature and humidity level of the environment in a manner that reduces premature failure risks.

The problems discussed above should be understood as being examples of problems solved by embodiments of the invention disclosed herein and the invention should not be limited to solving the same/similar problems. The disclosed invention is broadly applicable to address a range of problems beyond those discussed herein.

One or more embodiments of the invention may be implemented using instructions executed by one or more processors of the data management device. Further, such instructions may correspond to computer readable instructions that are stored on one or more non-transitory computer readable mediums.

While the invention has been described above with respect to a limited number of embodiments, those skilled in the art, having the benefit of this disclosure, will appreciate that other embodiments can be devised which do not depart from the scope of the invention as disclosed herein. Accordingly, the scope of the invention should be limited only by the attached claims.

What is claimed is:

1. A chassis, comprising:
a first computing component;
a second computing component;
an air mover that generates an airflow in the chassis used to thermally manage the first computing component and the second computing component; and
an airflow control component adapted to:
modify a first portion of the airflow proximate to the first computing component based on a corrosion rate of the first computing component without modifying a second portion of the airflow proximate to the second computing component.

2. The chassis of claim 1, wherein the airflow control component comprises:
a passive flapper adapted to modify the first portion of the airflow by:
deflecting the first portion of the airflow away from the first computing component when a temperature of an environment proximate to the first computing component is below a threshold; and
transmitting the first portion of the airflow towards the first computing component when the temperature of the environment proximate to the first computing component is above a second threshold.

3. The chassis of claim 2, wherein the passive flapper comprises:
a shape memory alloy that modifies its structure when the temperature of the shape memory alloy rises above the second threshold,
wherein the structure of the shape memory allow is adapted to:
block a path through which the portion of the airflow traverses when the structure of the shape memory allow is modified into a first shape, and
clear the path when the structure of the shape memory allow is modified into a second shape.

4. The chassis of claim 2, wherein the passive flapper comprises:
a valve that closes mechanically when the temperature falls below the threshold.

5. The chassis of claim 1, wherein the airflow control component comprises:
a sensor adapted to measure a corrosion rate of the first computing component;
an actuator; and
a computer programmed to:
initiate deflection, using the actuator, of the first portion of the airflow away from the first computing component while the corrosion rate is below a threshold; and
initiate direction, using the actuator, of the first portion of the airflow towards the first computing component while the corrosion rate is above a second threshold.

6. The chassis of claim 5, wherein the threshold and the second threshold are the same.

7. The chassis of claim 1, wherein the airflow control component comprises:
a sensor adapted to measure a corrosion rate of the computing component;
a heating component; and
a computer programmed to:
initiate an increase, using the heating component, of a temperature of the first computing component while the corrosion rate is above a threshold; and
initiate a decrease, using the heating component, of the temperature of the first computing component while the corrosion rate is below a second threshold.

8. A method for environmentally managing a chassis of an information handling system, comprising:
thermally managing a first computing component of the information handling system using a first portion of an airflow;
thermally managing a second computing component of the information handling system using a second portion of the airflow;
while thermally managing the first computing component and the second computing component:
modifying the first portion of the airflow based on a corrosion rate of the first computing component without modifying the second portion of the airflow.

9. The method of claim 8, wherein the first portion of the airflow is modified by:
deflecting, using a passive flapper, the first portion of the airflow away from the first computing component when a temperature of an environment proximate to the first computing component is below a threshold; and
transmitting, using the passive flapper, the first portion of the airflow towards the first computing component when the temperature of the environment proximate to the first computing component is above a second threshold.

10. The method of claim 9, wherein the passive flapper deflects the first portion of the airflow using a shape memory alloy that modifies its structure when the temperature of the shape memory alloy rises above the second threshold,
wherein the structure of the shape memory allow is adapted to:
block a path through which the first portion of the airflow traverses when the structure of the shape memory allow is modified into a first shape, and
clear the path when the structure of the shape memory allow is modified into a second shape.

11. The method of claim 9, wherein the passive flapper comprises:
a valve that closes mechanically when the temperature falls below the threshold.

12. The method of claim 8, wherein the first portion of the airflow is modified by:
measuring a corrosion rate of the first computing component;
initiating deflection, using an actuator, of the first portion of the airflow away from the first computing component while the corrosion rate is below a threshold; and
initiating direction, using the actuator, of the first portion of the airflow towards the first computing component while the corrosion rate is above a second threshold.

13. The method of claim 12, wherein the threshold and the second threshold are the same.

14. The method of claim 9, wherein the first portion of the airflow is modified by:
measuring a corrosion rate of the first computing component;
increasing a temperature of the first computing component while the corrosion rate is above a threshold; and
decreasing the temperature of the first computing component while the corrosion rate is below a second threshold.

15. A non-transitory computer readable medium comprising computer readable program code, which when executed by a computer processor enables the computer processor to perform a method for environmentally managing a chassis of an information handling system, the method comprising:
thermally managing a first computing component of the information handling system using a first portion of an airflow;
thermally managing a second computing component of the information handling system using a second portion of the airflow;
while thermally managing the first computing component and the second computing component:
modifying the first portion of the airflow based on a corrosion rate of the first computing component without modifying the second portion of the airflow.

16. The non-transitory computer readable medium of claim 15, wherein the first portion of the airflow is modified by:
deflecting, using a passive flapper, the first portion of the airflow away from the first computing component when a temperature of an environment proximate to the first computing component is below a threshold; and
transmitting, using the passive flapper, the first portion of the airflow towards the first computing component when the temperature of the environment proximate to the first computing component is above a second threshold.

17. The non-transitory computer readable medium of claim 16, wherein the passive flapper deflects the first portion of the airflow using a shape memory alloy that modifies its structure when the temperature of the shape memory alloy rises above the second threshold,
wherein the structure of the shape memory allow is adapted to:
block a path through which the first portion of the airflow traverses when the structure of the shape memory allow is modified into a first shape, and
clear the path when the structure of the shape memory allow is modified into a second shape.

18. The non-transitory computer readable medium of claim 16, wherein the passive flapper comprises:
a valve that closes mechanically when the temperature falls below the threshold.

19. The non-transitory computer readable medium of claim 15, wherein the first portion of the airflow is modified by:
measuring a corrosion rate of the first computing component;
initiating deflection, using an actuator, of the first portion of the airflow away from the first computing component while the corrosion rate is below a threshold; and
initiating direction, using the actuator, of the first portion of the airflow towards the first computing component while the corrosion rate is above a second threshold.

20. The non-transitory computer readable medium of claim 15, wherein the threshold and the second threshold are the same.
